(19) United States
(12) Patent Application Publication
(10) Pub. No.: US 2025/0183092 A1
(43) Pub. Date: Jun. 5, 2025

(54) CUP, SUBSTRATE PROCESSING APPARATUS, AND SUBSTRATE PROCESSING METHOD

(71) Applicant: TOKYO ELECTRON LIMITED, Tokyo (JP)

(72) Inventors: Kouichirou TANAKA, Koshi City (JP); Masahiro FUKUDA, Koshi City (JP); Kouichi HONTAKE, Koshi City (JP); Yusaku HASHIMOTO, Koshi City (JP); Hirofumi GOTO, Koshi City (JP)

(73) Assignee: TOKYO ELECTRON LIMITED, Tokyo (JP)

(21) Appl. No.: 18/964,386

(22) Filed: Nov. 30, 2024

(30) Foreign Application Priority Data
Dec. 1, 2023 (JP) 2023-204124

(51) Int. Cl. H01L 21/683; B25J 15/06; H01L 21/67; H01L 21/687

(52) U.S. Cl. CPC H01L 21/6838; B25J 15/0683; H01L 21/67051; H01L 21/68764

(57) ABSTRACT

A cup provided in a substrate processing apparatus for processing a substrate by supplying a processing liquid to the substrate includes an opening opened upwards to allow a transfer of the substrate; a suction opening for suctioning in a gas flowing toward the cup from above the cup; and an exhaust opening for exhausting the gas sucked in from the suction opening. The suction opening is opened upwards at an outer side than the opening. A flow path leading to the exhaust opening from the opening and a flow path leading to the exhaust opening from the suction opening are connected below the opening.

### CROSS-REFERENCE TO RELATED APPLICATION

This application claims priority under 35 U.S.C. § 119(a) to Japanese Patent Application No. 2023-204124 filed on Dec. 1, 2023, the entire disclosures of which are incorporated herein by reference.

### TECHNICAL FIELD

The various aspects and embodiments described herein pertain generally to a cup, a substrate processing apparatus, and a substrate processing method.

### BACKGROUND

Patent Document 1 discloses a liquid processing apparatus configured to process a surface of a substrate by supplying a coating liquid from a coating liquid supply through a coating liquid nozzle to the surface of the substrate that is held substantially horizontally by a substrate holder surrounded by a cup. This liquid processing apparatus includes a nozzle bath in which the coating liquid nozzle is placed to stand by; a nozzle transfer mechanism serving to transfer the coating liquid nozzle between the nozzle bath and a space above the substrate held by the substrate holder; an imaging device that images a leading end of the coating liquid nozzle being transferred by the nozzle transfer mechanism; a determiner that makes a determination upon whether the coating liquid has dripped or dropped from the leading end based on an imaging result from the imaging device; and a controller that causes the coating liquid supply and/or the nozzle transfer mechanism to perform a countermeasure operation when it is determined by the determiner that the coating liquid has dripped or dropped.
Patent Document 1: Japanese Patent Laid-open Publication No. 2008-135679

### SUMMARY

In an exemplary embodiment, a cup provided in a substrate processing apparatus configured to process a substrate by supplying a processing liquid to the substrate includes an opening opened upwards to allow a transfer of the substrate; a suction opening configured to suck in a gas flowing toward the cup from above the cup; and an exhaust opening configured to exhaust the gas sucked in from the suction opening. The suction opening is opened upwards at an outer side than the opening. A flow path leading to the exhaust opening from the opening and a flow path leading to the exhaust opening from the suction opening are connected below the opening.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a longitudinal cross sectional view illustrating a schematic configuration of a developing apparatus as a substrate processing apparatus according to an exemplary embodiment;

FIG. 2 is a transversal cross sectional view illustrating a schematic configuration of the developing apparatus as the substrate processing apparatus according to the exemplary embodiment;

FIG. 3 is a partial enlarged view of a cup shown in FIG. 1;

FIG. 4 is an explanatory diagram schematically illustrating a gas flow being exhausted;

FIG. 5 is a longitudinal cross sectional view illustrating another configuration example of the cup;

FIG. 6 is a longitudinal cross sectional view illustrating still another configuration example of the cup;

FIG. 7 is an explanatory diagram schematically illustrating a gas flow being exhausted;

FIG. 8 is a diagram illustrating another configuration example of a gas flow forming device; and

FIG. 9 is a diagram illustrating another configuration example of the gas flow forming device.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In a photolithography process in a manufacturing process for a semiconductor device or the like, there is performed a liquid processing in which a preset processing liquid is supplied onto a substrate such as a semiconductor wafer (hereinafter, simply referred to as “wafer”). The preset processing liquid is, for example, a developing liquid or a coating liquid configured to form a coating film.

In the aforementioned liquid processing, the substrate is rotated to diffuse the processing liquid supplied onto the substrate and to drain the processing liquid from the substrate. A liquid processing apparatus that performs this liquid processing, that is, a substrate processing apparatus is provided with a receptacle called a cup to suppress the processing liquid from scattering around from a surface of the substrate being rotated. Further, since the processing liquid may scatter in the form of mist from a peripheral portion of the substrate being rotated, evacuation is performed from a bottom of the cup to suppress the mist from floating above the cup and contaminating an outside of the cup.

In the liquid processing apparatus, when the evacuation is performed from the bottom of the cup, a gas flow heading toward an exhaust port provided in the bottom of the cup from above the cup is generated in a space where the cup is located. This gas flow causes an atmosphere near the surface of the substrate to flow from a central portion of the substrate toward the peripheral portion thereof, and this atmosphere is sucked into an exhaust path from a peripheral portion of the cup. Also, when the substrate is being rotated, the atmosphere directed to the central portion of the substrate is expelled from the peripheral portion of the substrate due to the rotation of the substrate. For these reasons, when evacuating the cup, the gas flow on the peripheral portion of the substrate gets stronger than the gas flow on the central portion of the substrate.

In a conventional cup structure, since the gas flow on the peripheral portion of the substrate is stronger than the gas flow on the central portion of the substrate as stated above, the temperature of the peripheral portion of the substrate tends to be higher than the temperature of the central portion of the substrate. As a result, when a developing liquid with high sensitivity to temperature is used, development results may be different between the peripheral portion and the central portion of the substrate. That is, in the conventional cup structure, a good processing may not be achieved because of the gas flow on the substrate within the cup.

In view of the foregoing, exemplary embodiments provide a technique capable of realizing the good processing by adjusting the gas flow on the substrate within the cup.

Hereinafter, a substrate processing apparatus and a cup belonging to the substrate processing apparatus according to an exemplary embodiment will be described with reference to the accompanying drawings, which form a part hereof. In the present specification and the various drawings, parts having substantially same functions and configurations will be assigned same reference numerals, and redundant descriptions thereof will be omitted.

### <Developing Apparatus>

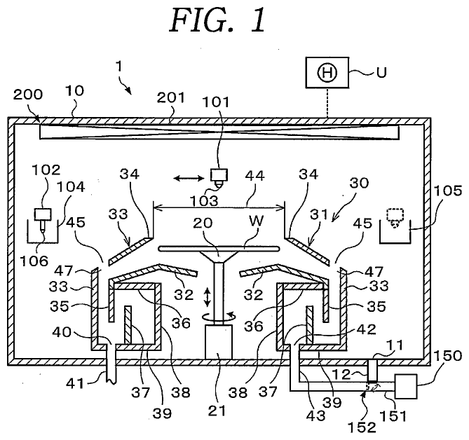

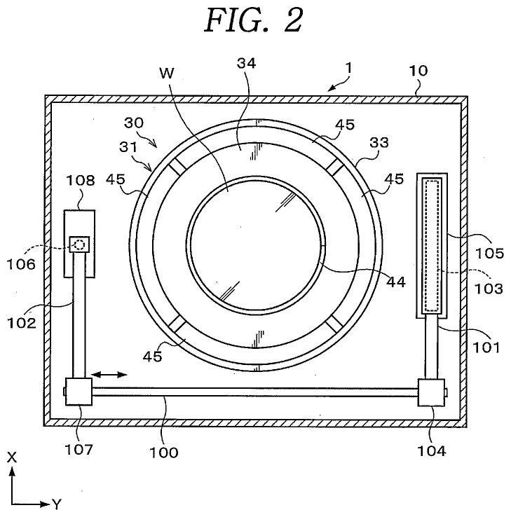

FIG. 1 and FIG. 2 are a longitudinal cross sectional view and a transversal cross sectional view illustrating a schematic configuration of a developing apparatus as a substrate processing apparatus according to an exemplary embodiment, respectively.

A developing apparatus 1 in FIG. 1 and FIG. 2 is configured to process a wafer W by supplying a developing liquid as a processing liquid to the wafer W as a substrate. The developing apparatus 1 includes a processing vessel 10 having a hermetically sealable inside. A carry-in/out opening (not shown) for the wafer W is formed in a side surface of the processing vessel 10.

A spin chuck 20 as a substrate holder configured to hold and rotate the wafer W is disposed in the processing vessel 10. The spin chuck 20 is connected to a chuck driver 21 as a rotating mechanism. The chuck driver 21 rotates the spin chuck 20 around a vertical axis, thus allowing the wafer W held by the spin chuck 20 to be rotated around the vertical axis. The chuck driver 21 has, for example, a motor as a power source that generates a driving power to rotate the spin chuck 20. The chuck driver 21 also moves the spin chuck 20 up and down, thus allowing the wafer W held by the spin chuck 20 to be moved up and down. The chuck driver 21 has, for example, a cylinder as a power source that generates a driving power to move the spin chuck 20 up and down.

A plurality of (e.g., three) elevating pins (not shown) is provided in an area on the rear side of the wafer W held by the spin chuck 20. The elevating pins serve an elevating member configured to deliver the wafer W between the spin chuck 20 and a wafer transfer mechanism outside the developing apparatus 1. The elevating pins are configured to be movable up and down by a pin driver (not shown) having a motor, a cylinder, or the like.

The processing vessel 10 is also provided with a cup 30 which accommodates the spin chuck 20 and from a bottom of which a gas is exhausted. The cup 30 is a receptacle that receives and collects a liquid scattering or dropping from the wafer W. The cup 30 will be elaborated later.

A rail 100 is formed on the negative X-axis side (lower part of FIG. 2) of the cup 30, extending along the Y-direction (left-and-right direction in FIG. 2). For example, the rail 100 is formed to extend from an outside of the cup 30 on the negative Y-axis side (left side of FIG. 2) to an outside of the cup 30 on the positive Y-axis side (right side of FIG. 2). The rail 100 is provided with arms 101 and 102.

Supported by the arm 101 is a developing liquid nozzle 103 as a processing liquid supply, configured to supply a resist liquid as a processing liquid. Specifically, the developing liquid nozzle 103 supplies a developing liquid to the wafer W held by the spin chuck 20. The developing liquid nozzle 103 is formed in the shape of a square tube having a developing liquid discharge opening at a bottom surface thereof. The discharge opening of the developing liquid nozzle 103 is formed in a rectangular shape when viewed from the top, and the length of the discharge opening in a lengthwise direction is approximately the same as the diameter of the wafer W.

The developing liquid nozzle 103 may be a liquid contact nozzle. The liquid contact nozzle is a nozzle having: a discharge opening configured to discharge the developing liquid; and a lower end surface enlarged in a transversal direction from the discharge opening and approximately parallel to a surface of the wafer W.

The arm 101 is movable on the rail 100 by a nozzle driver 104. This allows the developing liquid nozzle 103 to be moved from a standby section 105 provided outside the cup 30 on the positive Y-axis side to above a center of the wafer W within the cup 30. Also, the arm 101 is movable up and down by the nozzle driver 104, so the height of the developing liquid nozzle 103 can be adjusted. A motor or a cylinder is used as a power source that generates a driving power for driving the movement of the first arm 101 along the rail 100 and the elevating movement of the arm 101.

Supported by the arm 102 is a rinse liquid nozzle 106 as another processing liquid supply, configured to supply a rinse liquid as a processing liquid. Specifically, the rinse liquid nozzle 106 supplies a rinse liquid to the wafer W held by the spin chuck 20.

The arm 102 is movable on the rail 100 by a nozzle driver 107. This allows the rinse liquid nozzle 106 to be moved from a standby section 108 provided outside the cup 30 on the negative Y-axis side to above the center of the wafer W within the cup 30. Also, the arm 102 is movable up and down by the nozzle driver 107, so the height of the rinse liquid nozzle 106 can be adjusted. A motor or a cylinder is used as a power source that generates a driving power for driving the movement of the second arm 102 along the rail 100 and the elevating movement of the arm 102.

The developing liquid nozzle 103 and the rinse liquid nozzle 106 are respectively connected to supply sources for the developing liquid and the rinse liquid via flow rate controllers (not shown), respectively. The developing liquid and the rinse liquid from the supply sources are respectively supplied to the developing liquid nozzle 103 and the rinse liquid nozzle 106 with their flow rates adjusted by the flow rate controllers, and are then discharged onto the wafer W on the spin chuck 20 through the nozzles 103 and 106, respectively. The flow rate controller includes, for example, various valves and a mass flow controller.

Furthermore, an exhaust opening 11 is formed in a bottom wall of the processing vessel 10, as shown in FIG. 1. An exhaust pipe 12 for evacuating the processing vessel 10 is connected to this exhaust opening 11. The exhaust pipe 12 is connected to an exhaust mechanism 150 having an exhaust pump, etc., via a main exhaust pipe 151.

In addition, a gas flow forming device 200 is provided above the cup 30 in the processing vessel 10. The gas flow forming device 200 generates a downflow from above the cup 30. The gas flow forming device 200 has a fan filter unit (FFU) 201 as a blower. The FFU 201 is provided above the cup 30 and blows out a gas (specifically, clean air) downwards.

The developing apparatus 1 described above is provided with a controller U. The controller U is, for example, a computer equipped with a processor such as a CPU and a memory, and has a program storage (not shown). The program storage stores a program for implementing a wafer processing performed by using the developing apparatus 1. The program may be recorded on a computer-readable recording medium H and installed from the recording medium H into the controller U. The recording medium H may be transitory or non-transitory. Also, a part or all of the program may be implemented by hardware (circuit board). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality.

### <Structure of Cup 30>

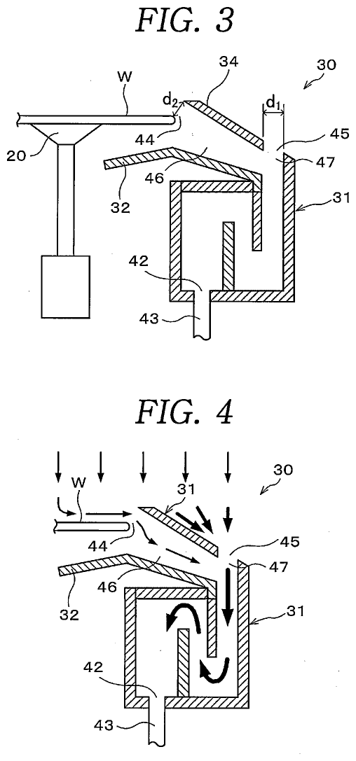

Now, details of the structure of the cup 30 will be explained with reference to FIG. 3 and FIG. 4 in conjunction with FIG. 1 and FIG. 2. FIG. 3 is a partial enlarged view of the cup 30 shown in FIG. 1. FIG. 4 is an explanatory diagram schematically illustrating a gas flow being exhausted. In FIG. 4, black bold arrows indicate the gas flow, and the thickness of each arrow indicates the magnitude of a flow rate of a gas.

The cup 30 includes an outer cup 31 and an inner cup 32, as illustrated in FIG. 1.

The outer cup 31 is a component that constitutes an outer wall of the cup 30. The outer cup 31 has an outer peripheral wall 33 and an inclined wall 34.

The outer peripheral wall 33 is of a cylindrical shape.

The inclined wall 34 is formed in a cylindrical shape and, also, a circular ring shape when viewed from the top. A lower end of the inclined wall 34 is located lower than the wafer W held by the spin chuck 20, and is connected to an upper end of the outer peripheral wall 33. An upper end of the inclined wall 34 is located higher than the wafer W held by the spin chuck 20. In addition, the upper end of the inclined wall 34 is located further inward than the lower end, so the inclined wall 34 is inclined inwards from the lower end toward the upper end.

The inner cup 32 is provided inside the outer cup 31. A cylindrical wall 35 is provided at a lower portion of the inner cup 32. A gap forming a discharge path is formed between this wall 35 and the outer peripheral wall 33 of the outer cup 31. In addition, a curved path is formed under the inner cup 32 by a circular ring-shaped horizontal member 36, a cylindrical outer peripheral vertical member 37, a cylindrical inner peripheral vertical member 38, and a circular ring-shaped bottom member 39 located at the bottom. This curved path constitutes a gas-liquid separation section.

A drain port 40 for draining a collected liquid is formed in the bottom member 39 between the outer peripheral wall 33 of the outer cup 31 and the outer peripheral vertical member 37, and a drain pipe 41 is connected to this drain port 40. Meanwhile, an exhaust opening 42 for exhausting an atmosphere around the wafer W is formed in the bottom member 39 between the outer peripheral vertical member 37 and the inner peripheral vertical member 38, and an exhaust pipe 43 is connected to this exhaust opening 42.

Like the exhaust pipe 12 described above, the exhaust pipe 43 is connected to the exhaust mechanism 150 via the main exhaust pipe 151.

The main exhaust pipe 151 is provided with a damper 152 configured to perform a switchover between evacuation of the processing vessel 10 through the exhaust pipe 12 (hereafter, referred to as “module evacuation”) and evacuation of the cup 30 through the exhaust pipe 43 (hereafter, referred to as “cup evacuation”).

An opening 44 opened upwards is formed above the inner cup 32 in order to allow a transfer of the wafer W to/from the spin chuck 20. The opening 44 is formed by an inner peripheral surface of an upper end of the outer cup 31. Specifically, the opening 44 is formed by an inner peripheral surface of an upper end of the inclined wall 34 of the outer cup 31.

Furthermore, the cup 30 has a suction opening 45 through which a gas heading toward the cup 30 from above the cup 30 is sucked in. The suction opening 45 is provided at a peripheral portion of the inclined wall 34 of the outer cup 31 so as to penetrate the inclined wall 34. The suction opening 45 is plural in number, and these suction openings 45 are arranged at a certain distance therebetween in a circumferential direction. Each suction opening 45 is formed to have a circular arc shape when viewed from the top.

These suction openings 45 are opened upwards. Therefore, upward openings formed in the cup 30 include the opening 44 for the transfer of the wafer W and the suction openings 45 provided at an outer side than the opening 44.

As shown in FIG. 3, the cup 30 having the suction openings 45 described above has, as exhaust paths, a flow path 46 extending from the opening 44 to the exhaust opening 42 and a flow path 47 extending from the suction opening 45 to the exhaust opening 42. These flow paths 46 and 47 are connected to each other below the opening 44, that is, below the wafer W held by the spin chuck 20. Therefore, a gas flow heading toward the exhaust opening 42 from a gap between the wafer W held by the spin chuck 20 and the outer cup 31 passes through the flow path 46 and merges with a gas flow passing through the flow path 47.

The size of the suction opening 45 is appropriately set based on a rotation speed of the spin chuck 20 and an exhaust amount. It is desirable that a width d₁ of the suction opening 45 is larger than a gap d₂ between an edge of the wafer W held by the spin chuck 20 and the outer cup 31. This allows a flow rate of the gas sucked from the suction opening 45 to be greater than a flow rate of the gas sucked from the gap between the wafer W and the outer cup 31, so that the evacuation from the suction opening 45 can be accelerated.

### <Wafer Processing>

Now, an example of a wafer processing performed by using the developing apparatus 1 configured as described above will be explained. The following processing is performed under the control of the controller U.

Further, in the following description, it is assumed that a resist film is formed on the surface of the wafer W before the wafer W is carried into the developing apparatus 1 and that an exposure processing and a subsequent heating processing on the resist film are completed. During the processing, a downward flow from above the cup 30 is continuously formed by the gas flow forming device 200.

(Process S1: Holding of wafer W)

First, the wafer W passes through the opening 44 of the cup 30 and is held by the spin chuck 20.

Specifically, the wafer transfer mechanism (not shown) holding the wafer W is first advanced into the processing vessel 10 from the outside of the processing vessel 10 through the carry-in/out opening (not shown) provided in the side surface of the processing vessel 10. The wafer W is then transferred to above the spin chuck 20. Next, the elevating pins are moved up and down, so that the wafer W is transferred onto a top surface of the spin chuck 20 through the opening 44. The wafer W is then attracted to and held by the spin chuck 20.

In this process, the damper 152 is adjusted such that the module evacuation, between the module evacuation and the cup evacuation, is performed.

(Process S2: Processing with Developing Liquid)

Subsequently, the wafer W held by the spin chuck 20 is subjected to a processing with a developing liquid. As a specific example, supply of the developing liquid (process S2A) and stationary development (process S2B) are performed.

### (Process S2A: Supply of Developing Liquid)

In this process, the developing liquid is supplied to the wafer W held by the spin chuck 20, so that a developing liquid film is formed on the wafer W.

Specifically, the developing liquid nozzle 103 is moved to above the wafer W. Then, the supply of the developing liquid from the developing liquid nozzle 103 onto the wafer W is started, so a puddle of the developing liquid, that is, the developing liquid film is formed. By way of example, when forming the developing liquid film, a discharge destination of the developing liquid from the developing liquid nozzle 103 is fixed to the center of the wafer W in the extension direction of the rail 100, and in this state, the wafer W is rotated at a low speed (e.g., 100 rpm or less). Once the developing liquid film is formed, the supply of the developing liquid from the developing liquid nozzle 103 is stopped, and the rotation of the wafer W is also stopped. Thereafter, the developing liquid nozzle 103 is retreated from above the wafer W.

In this process, the damper 152 is adjusted such that the cup evacuation, between the module evacuation and the cup evacuation, is performed. This makes it possible to suppress mist of the developing liquid from leaking out of the cup 30. The mist of the developing liquid is generated as a result of, for example, the developing liquid discharged from the developing liquid nozzle 103 colliding with the wafer W.

When the cup evacuation is being performed in this way, that is, when the evacuation is being performed from the bottom of the cup 30, there is a tendency for the gas flow to become stronger at the wafer periphery than at the wafer center as stated above. To elaborate, the velocity of the gas flow along the wafer W tends to be higher at the wafer periphery than at the wafer center.

As a resolution, in the developing apparatus 1, the gas heading toward the cup 30 from above the cup 30 can be exhausted through the suction opening 45. That is, since another exhaust path different from the opening 44 is provided, the exhaust flow rate from the peripheral portion of the wafer W can be reduced. Therefore, even if the cup evacuation is performed in the present process, it is possible to suppress the gas flow from becoming stronger at the wafer periphery than at the wafer center. Specifically, a difference in the flow velocity between the wafer center and the wafer periphery can be reduced. As a result, it is possible to reduce a difference in the temperature of the developing liquid between the wafer center and the wafer periphery upon the completion of the process.

### (Process S2B: Stationary Development)

In this process, the developing liquid film formed in the process S2A is maintained on the wafer W for a predetermined time, and stationary development of the resist film on the wafer W is performed.

In addition, in this process, a state in which the damper 152 is adjusted such that the module evacuation is performed and the cup evacuation is not performed is maintained. This makes it possible to suppress generation of a gas flow around the peripheral portion of the wafer W during the stationary development.

(Process S3: Processing with Rinse Liquid)

Then, a processing with a rinse liquid, that is, a cleaning processing is performed on the wafer W held by the spin chuck 20.

To elaborate, the rinse liquid nozzle 106 is moved to above the center of the wafer W. The rinse liquid is supplied from the rinse liquid nozzle 106 onto the wafer W, so that the wafer W is cleaned. For example, during this cleaning processing, the rinse liquid is supplied from the rinse liquid nozzle 106 onto the wafer W which is being rotated at a first rotation speed T1, which is higher than a rotation speed of the wafer W during the supply of the developing liquid in the process S2A, and the developing liquid film on the wafer W is replaced with the rinse liquid. The first rotation speed T1 is, for example, 100 rpm to 500 rpm. Thereafter, the supply of the rinse liquid is stopped, and the rotation speed of the wafer W is raised to a second rotation speed T2 (>T1). As a result, the rinse liquid is shaken off from the wafer W, that is, the wafer W is dried. During this drying, the rinse liquid nozzle 106 is retreated from above the wafer W.

In this process, the damper 152 is adjusted such that the cup evacuation, between the module evacuation and the cup evacuation, is performed. This makes it possible to suppress mist of the rinse liquid or the developing liquid from leaking out of the cup 30. Further, in this process, the mist of the rinse liquid or developing liquid may be generated as a result of the rinse liquid supplied from the rinse liquid nozzle 106 colliding with the wafer W, or as a result of the rinse liquid or developing liquid shaken off from the wafer W colliding with the outer cup 31, for example.

### (Process S4: Carrying-Out of Wafer)

Then, the wafer W is carried out of the developing apparatus 1 in the reverse sequence as in the process S1.

Thus, the series of processes of the wafer processing are completed.

### <Main Effects of Present Exemplary Embodiment>

In the cup 30 according to the present exemplary embodiment described above, since the suction opening 45 is formed at an outer side than the opening 44 that is provided for the transfer of the wafer W, the gas flowing from above the cup 30 toward the cup 30 can be exhausted through the suction opening 45. That is, since the exhaust path other than the opening 44 is provided, the exhaust flow rate from the peripheral portion of the wafer W can be reduced. Accordingly, the difference in the flow velocity between the central portion and the peripheral portion of the wafer W can be reduced. That is, the gas flow on the wafer W in the cup 30 is adjusted. As a result, the difference in the temperature of the developing liquid between the central portion of the wafer and the peripheral portion of the wafer can be reduced. In particular, when the development is progressing as the developing liquid is supplied while the cup evacuation is being performed, that is, in the process S2A, the difference in the temperature of the developing liquid between the central portion and the peripheral portion of the wafer can be suppressed. Therefore, even when the developing liquid with high temperature sensitivity is used, the difference in the development result between the peripheral portion and the central portion of the wafer can be suppressed. That is, according to the present exemplary embodiment, the good processing can be realized by adjusting the gas flow for the wafer W in the cup 30. Here, the development result specifically refers to a dimension such as a line width of a resist pattern after being developed.

### <Other Examples of Cup>

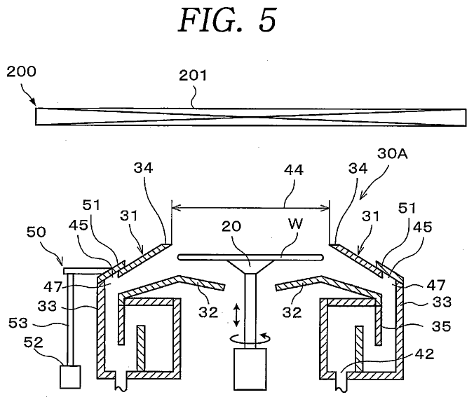

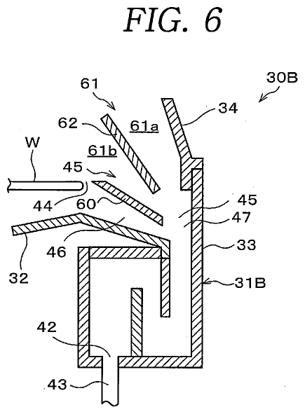

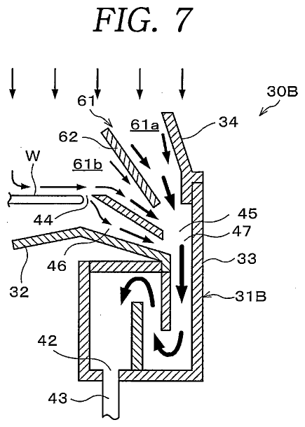

Now, other configuration examples of the cup will be explained with reference to FIG. 5 to FIG. 7. FIG. 5 is a longitudinal cross sectional view illustrating another configuration example of the cup. FIG. 6 is a longitudinal cross sectional view illustrating still another configuration example of the cup. FIG. 7 is an explanatory diagram illustrating a gas flow being exhausted. In FIG. 7, black bold arrows indicate the gas flow, and the thickness of each arrow indicates the magnitude of a flow rate of a gas.

A cup 30A in FIG. 5 is provided with an opening/closing device 50 configured to open and close the suction opening 45.

The opening/closing device 50 has a cover member 51 and an elevating mechanism 52 as a retreating mechanism configured to retreat the cover member 51.

The cover member 51 is formed in a circular ring shape when viewed from the top so as to cover the suction opening 45. The cover member 51 is connected to the elevating mechanism 52 via a supporting member 53. The elevating mechanism 52 allows the cover member 51 to be retreated from the cup 30, and, more specifically, allows the cover member 51 to be moved up and down with respect to the cup 30. More specifically, the cover member 51 is allowed, by the elevating mechanism 52, to be movable between a first position and a second position. The first position is a position where the cover member 51 is located on a surface of the cup 30 where the suction openings 45 are formed, that is, on an outer peripheral surface of a lower end portion of the inclined wall 34, so as to completely cover each suction opening 45. The second position is a position retreated upwards from the first position, where the cover member 51 does not interfere with the wafer W when the wafer W is handed over between the spin chuck 20 and the wafer transfer mechanism via the elevating pins (not shown). The elevating mechanism 52 has, for example, a cylinder as a power source configured to generate a driving power for driving the up-and-down movement of the cover member 51.

The timing when the cover member 51 is placed at the aforementioned second position so the suction opening 45 is turned open is when the mist of the processing liquid is unlikely to leak out of the cup 30 through the suction opening 45.

Meanwhile, the timing when the cover member 51 is placed at the aforementioned first position and the suction opening 45 is closed is when the mist of the processing liquid is highly likely to leak out of the cup 30 through the suction opening 45.

The time when the mist of the processing liquid is unlikely to leak out of the cup 30 through the suction opening 45 is when the rotation speed of the wafer W is low (including when the wafer W is not rotated). Specifically, the time when the leakage is unlikely to occur is when the developing liquid is supplied in the process S2A and when the stationary development is performed in the process S2B in the above-described wafer processing.

Also, the time when the mist of the processing liquid is highly likely to leak out of the cup 30 through the suction opening 45 is when the rotation speed of the wafer W is high. Specifically, the time when the leakage is highly likely to occur is when the wafer W is dried in the process S3 of the above-described wafer processing, in which the wafer W is rotated at the second rotation speed T2 in the state that the supply of the processing liquid such as the developing liquid or the rinse liquid is stopped.

In addition, when the wafer W is rotated at the first rotation speed T1 while supplying the rinse liquid in the process S3 of the above-described wafer processing, the cover member 51 may be located at either the first position or the second position.

Further, during the processing with the rinse liquid in the process S3 of the above-described wafer processing, the development does not progress, so even if the suction opening 45 is closed and the gas flow around the wafer gets stronger, the effect on the development result would be small.

With the above-described cup 30A, when the gas flow around the peripheral portion of the wafer is strong to have an adverse effect on the development result, the suction opening 45 can be opened to weaken the gas flow around the peripheral portion of the wafer W. Also, with the cup 30A, when there is a high possibility that the mist of the processing liquid leaks out of the cup 30 through the suction opening 45, the leakage of the mist through the suction opening 45 can be suppressed by closing the suction opening 45.

That is, with the cup 30A, it is both possible to weaken the gas flow around the peripheral portion of the wafer and to suppress the mist of the processing liquid from leaking out of the cup 30A.

A cup 30B in FIG. 6 and FIG. 7 are used in, for example, a coating apparatus. In the coating apparatus, a coating liquid as a processing liquid is supplied to the wafer W to process the wafer W and form a coating film. The coating film is, by way of example, a resist film.

Unlike the cup 30 shown in FIG. 1, the cup 30B has an intermediate cup 60 located above the inner cup 32.

The intermediate cup 60 is formed in a circular ring shape when viewed from the top. The aforementioned opening 44 is formed by an upper end inner peripheral surface of this intermediate cup 60. A lower end of the intermediate cup 60 is located at an outer side than an upper end thereof, and the intermediate cup 60 is inclined outwards from the upper end toward the lower end thereof.

Further, the aforementioned suction opening 45 is formed by an outer peripheral surface of the lower end of the intermediate cup 60 and an inner peripheral surface of an outer peripheral wall of an outer cup 31B.

The intermediate cup 60 may be supported by the outer cup 31B or the inner cup 32.

The cup 30B is provided with a suction path 61 which is formed between the intermediate cup 60 and the outer cup 31B. This suction path 61 is opened upwards and guides a gas flow heading toward the cup 30B from above it into the suction opening 45.

Also, in the outer cup 31B, unlike in the outer cup 31 shown in FIG. 1, etc., the outer peripheral wall 33 and the inclined wall 34 are configured as separate parts.

Furthermore, the cup 30B has a division cup 62 provided above the intermediate cup 60.

The division cup 62 is formed in a circular ring shape. An upper end of the division cup 62 is located higher than the suction opening 45. The upper end of the division cup 62 is located at an inner side than a lower end thereof, and the division cup 62 is inclined inwards from the lower end toward the upper end thereof.

The division cup 62 may be supported by the outer cup 31B or the intermediate cup 60.

In the cup 30B, the suction path 61 is divided into an inner portion and an outer portion by the division cup 62. That is, the suction path 61 has an outer suction path 61a which is a flow path between the outer cup 31B and the division cup 62, and an inner suction path 61b which is a flow path between the intermediate cup 60 and the division cup 62. In the cup 30B having this suction path 61, gas flows respectively passing through the outer suction path 61a and the inner suction path 61b are formed during the evacuation.

With the suction path 61 described above, the gas flow heading toward the suction opening 45 from above the cup 30 is rectified, so that generation of a vortex flow near the suction opening 45 can be suppressed. This suppresses staying of the gas near the suction opening 45, so that the evacuation from the suction opening 45 is accelerated.

In addition, since the generation of the vortex flow is suppressed, a backflow from a downstream end of the flow path 46, which is formed by the inner cup 32 and the intermediate cup 60, into the suction path 61 through the suction opening 45 can be suppressed. Therefore, it is possible to suppress the mist of the processing liquid passing through the flow path 46 from flowing back into the suction path 61, which in turn makes it possible to suppress the mist of the processing liquid from leaking out of the cup 30B.

In order to enhance the effect of suppressing the backflow into the suction path 61, it is desirable that the cross sectional area of the suction path 61 decreases from an upstream side toward a downstream side of the suction path 61. This increases a suction pressure at the downstream end of the suction path 61, so that the effect of suppressing the backflow into the suction path 61 can be enhanced.

In addition, when the outer suction path 61a and the inner suction path 61b are provided, it is desirable that the cross sectional area of at least one of the outer suction path 61a and the inner suction path 61b decreases from the upstream side toward the downstream side. By way of example, as shown in FIG. 6 and FIG. 7, when the cross sectional area of each of the suction paths 61a and 61b gradually decreases, the suction pressure at the downstream end of each of the suction paths 61a and 61b increases. This makes it possible to suppress not only the backflow from the downstream end of the flow path 46 into the suction path 61 but also a backflow between the outer suction path 61a and the inner suction path 61b.

Furthermore, by providing the outer cup 31B and the division cup 62 in addition to the intermediate cup 60 that forms the opening 44, the effect of receiving and recovering the processing liquid scattered from the wafer W held by the spin chuck 20 can be improved.

In addition, it is desirable that a pressure loss that occurs when the gas passes through the inner suction path 61b is greater than a pressure loss when the gas passes through the outer suction path 61a. By way of example, by reducing the width of the flow path (specifically, reducing the minimum cross sectional area of the flow path), or by reducing the opening ratio of the opening that forms the flow path, the pressure loss in that flow path can be increased.

When the pressure loss in the inner suction path 61b is greater than the pressure loss in the outer suction path 61a, the flow rate of the gas passing through the outer suction path 61a becomes greater than the flow rate of the gas passing through the inner suction path 61b. As a result, the evacuation is accelerated at a position farther away from the peripheral portion of the wafer W. In other world, the flow rate of the gas flowing around the peripheral portion of the wafer W is reduced, so that the difference in the flow velocity between the gas flow at the central portion of the wafer W and the gas flow at the peripheral portion of the wafer W can be reduced.

Further, when the pressure loss in the inner suction path 61b is greater than the pressure loss in the outer suction path 61a, the flow rate of the gas passing through the inner suction path 61b is small. Therefore, it is possible to suppress the mist of the processing liquid from passing through the inner suction path 61b from the wafer W held by the spin chuck 20, flowing back through the outer suction path 61a, and being ejected out of the cup 30B.

Furthermore, when the pressure loss in the inner suction path 61b is greater than the pressure loss in the outer suction path 61a, the flow rate of the gas passing through the outer suction path 61a is large during the module evacuation. Therefore, when switching from the cup evacuation to the module evacuation, the flow rate of the gas heading toward the suction opening 45 by inertia in the outer suction path 61a is also large. Thus, when switching from the cup evacuation to the module evacuation, it is possible to suppress the mist of the processing liquid, which has been present below the suction opening 45 within the cup 30B, from flowing back through the outer suction path 61a and being ejected out of the cup 30B. That is, it is possible to suppress a backdraft when the cup evacuation is switched to the module evacuation.

### <Modification Example of Cup 30B>

The above-described configuration of the cup 30B having the suction path 61 is just one example, and the cup 30B having the suction path 61 may be configured as follows, as another example.

That is, in the cup 30B, the division cup 62 may be omitted. Also, the cup 30B may not have the inclined wall 34. Furthermore, both the division cup 62 and the inclined wall 34 may be omitted in the cup 30B.

### <Other Examples of Gas Flow Forming Device>

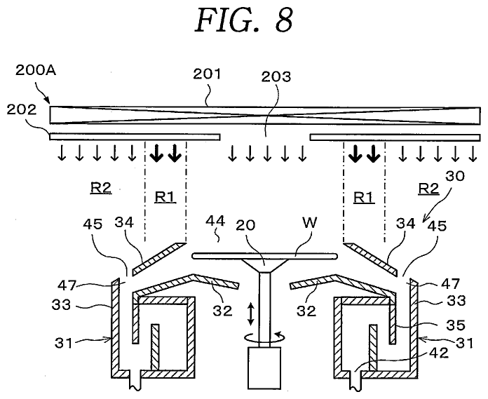

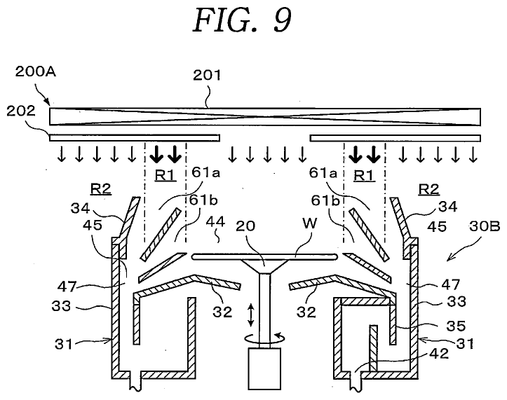

Now, other configuration examples of the gas flow forming device will be explained with reference to FIG. 8 and FIG. 9. FIG. 8 and FIG. 9 are diagrams respectively illustrating other configuration examples of the gas flow forming device. Black bold arrows in FIG. 8 and FIG. 9 indicate a gas flow from the gas flow forming device, and the thickness of each arrow indicates the magnitude of a flow rate of a gas.

The gas flow forming device 200A of FIG. 8 has a flow rectifying plate 202 in addition to the FFU 201. The flow rectifying plate 202 is provided between the cup 30 and the FFU 201, and serves as a gas flow forming member that forms a downward flow from the gas blown out from the FFU 201.

The flow rectifying plate 202 has a gas flow forming device side opening 203 (hereinafter, simply referred to as device side opening 203).

The device side opening 203 is provided at a position facing the spin chuck 20, and forms a gas flow heading toward the wafer W held by the spin chuck 20.

Further, the flow rectifying plate 202 forms, in a region R1 surrounding an outer periphery of the device side opening 203 when viewed from the top, a gas flow that is stronger than a gas flow in a region R2 outside the region R1. Hereinafter, the regions R1 and R2 may sometimes be referred to as a strong flow forming region R1 and a weak flow forming region R2, respectively.

The flow rectifying plate 202 is provided with a discharge hole (not shown) through which the gas from the FFU 201 passes to be discharged downwards. The discharge hole is plural in number, and these discharge holes are formed in a region of the flow rectifying plate 200 facing the strong flow forming region R2 and a region of the flow rectifying plate 202 facing the weak flow forming region R1. A first opening ratio, which is the ratio of the discharge holes in the region of the flow rectifying plate 202 facing the strong flow forming region R1 is lower than a second opening ratio, which is the ratio of the discharge holes in the region of the flow rectifying plate 202 facing the weak flow forming region R2. As a result, the flow velocity of the flow of the gas discharged from the discharge holes in the region facing the strong flow forming region R1 becomes faster than the flow velocity of the flow of the gas discharged from the discharge holes in the region facing the weak flow forming region R2. That is, a gas flow stronger than that in the weak flow forming region R2 can be formed in the strong flow forming region R1.

The strong gas flow formed in the strong flow forming region R1 functions as an air curtain. Therefore, it is possible to suppress an external factor existing in the weak flow forming region R2 from affecting a region at an inner side than the strong flow forming region R1. Specifically, it is possible to suppress particles in the weak flow forming region R2 from being included in a gas flow heading downwards from the device side opening 203, i.e., a gas flow heading toward the wafer W.

The cup 30 shown in FIG. 1, etc., can also be used in a liquid processing apparatus using the gas flow forming device 200A as described above.

In this case, in the flow rectifying plate 202, it is desirable that the above-described strong gas flow is formed at an outer side than the opening 44 of the cup 30, when viewed from the top. That is, it is desirable to form the strong gas flow such that the strong flow forming region R1 surrounds the outer periphery of the opening 44 of the cup 30, when viewed from the top.

This makes it possible to suppress the above-described strong gas flow from reaching only the peripheral portion of the wafer W without reaching the central portion of the wafer W. As a result, it is possible to suppress an increase of a difference in the flow velocity of the gas flow between the central portion and peripheral portion of the wafer, which might be caused due to the influence of the strong gas flow.

The device side opening 203 is desirably formed as follows. That is, it is desirable that the device side opening 203 is formed such that the whole of it is located inside the circumferential edge of the wafer W held by the spin chuck 20 when viewed from the top. Specifically, the diameter of the device side opening 203 is desirably in the range of 30% to 90% of the diameter of the wafer W. This makes it possible to strengthen the gas flow from the device side opening 203, as compared to a case where the flow rectifying plate 202 is not provided. Further, the strong gas flow from the device side opening 203 can be made to be concentrated on the center side of the wafer W. Therefore, even when the temperature of the central portion of the wafer is less likely to become lower than the temperature of the peripheral portion of the wafer, a temperature difference between the central portion and the peripheral portion of the wafer can still be suppressed.

Furthermore, the cup 30B shown in FIG. 6, etc., may be used in a liquid processing apparatus in which the gas flow forming device 200A described above is used.

In this case, it is desirable that an inner peripheral edge of the upper end of the outer suction path 61a is located outside the device side opening 203 when viewed from the top. With this configuration, it is possible to suppress the gas flow heading toward the wafer W from the device side opening 203 from being affected by the suctioning through the outer suction path 61a.

So far, the cup according to the present disclosure has been described. The shapes of the components of the cup described in the present specification are merely examples, and the specific shapes are determined appropriately depending on the type of the gas exhausted from the cup, the evacuation capacity of the substrate processing apparatus, the processing liquid to be supplied to the wafer surface, and so forth. By way of example, each cup component constituting the suction path 61 may have a curved surface to enhance the rectifying effect. Also, each cup component constituting the suction path 61 may have a bending surface as long as a flow rectifying effect can be obtained.

The cup and the substrate processing apparatus according to the present disclosure may also be applicable to a processing apparatus configured to process a processing target substrate other than the semiconductor wafer, such as a FPD (flat panel display) substrate.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

In addition, the following configuration examples are also within the technical scope of the present disclosure.

(1) A cup provided in a substrate processing apparatus configured to process a substrate by supplying a processing liquid to the substrate, the cup including:
an opening opened upwards to allow a transfer of the substrate;
a suction opening configured to suck in a gas flowing toward the cup from above the cup; and
an exhaust opening configured to exhaust the gas sucked in from the suction opening,
wherein the suction opening is opened upwards at an outer side than the opening, and
a flow path leading to the exhaust opening from the opening and a flow path leading to the exhaust opening from the suction opening are connected below the opening.

(2) The cup described in (1), further including:
an opening/closing device configured to open or close the suction opening.

(3) The cup described in (1) or (2), further including:
a suction path configured to guide a gas flow to the suction opening,
wherein an upper end of the suction path is opened upwards,
the suction path is divided into an inner portion and an outer portion, and
a pressure loss that occurs when a gas passes through the inner portion of the suction path is greater than a pressure loss that occurs when the gas passes through the outer portion of the suction path.

(4) A substrate processing apparatus configured to process a substrate by supplying a processing liquid to the substrate, the substrate processing apparatus including:
a substrate holder configured to hold and rotate the substrate;
a processing liquid supply configured to supply the processing liquid to the substrate; and
a cup accommodating the substrate holder,
wherein the cup includes:
an opening opened upwards to allow a transfer of the substrate;
a suction opening configured to suck in a gas flowing toward the cup from above the cup; and
an exhaust opening configured to exhaust the gas sucked in from the suction opening,
the suction opening is opened upwards at an outer side than the opening, and
a flow path leading to the exhaust opening from the opening and a flow path leading to the exhaust opening from the suction opening are connected below the opening.

(5) The substrate processing apparatus described in (4), further including:
a gas flow forming device configured to generate a downward gas flow from above the cup,
wherein the gas flow forming device includes:
a blower provided above the cup, and configured to blow out a gas downwards; and
a gas flow forming member provided between the cup and the blower, and configured to form the downward gas flow from the gas blown out from the blower,
the gas flow forming member has, at a position facing the substrate holder, a device side opening, which is another opening through which a gas flow heading toward the substrate held by the substrate holder is formed, and
the gas flow forming member forms a strong gas flow in a first region surrounding an outer periphery of the device side opening when viewed from a top, than in a second region outside the first region.

(6) The substrate processing apparatus described in (5), further including:
a suction path configured to guide the gas flow to the suction opening,
wherein an upper end of the suction path is opened upwards,
the suction path is divided into an inner portion and an outer portion,
a pressure loss that occurs when a gas passes through the inner portion of the suction path is greater than a pressure loss that occurs when the gas passes through the outer portion of the suction path, and
an inner peripheral edge of an upper end of the outer portion of the suction path is located at an outer side of the device side opening, when viewed from the top.

(7) The substrate processing apparatus described in (5) or (6),
wherein the gas flow forming member forms the strong gas flow at an outer side than the opening of the cup when viewed from the top.

(8) The substrate processing apparatus described in any one of (5) to (7),
wherein an entire of the device side opening is located at an inner side than a circumferential edge of the substrate held by the substrate holder, when viewed from the top.

(9) The substrate processing apparatus described in any one of (4) to (8),
wherein the cup further includes an opening/closing device configured to open or close the suction opening,
the substrate processing apparatus further includes a controller,
the controller performs:
supplying the processing liquid to the substrate held by the substrate holder; and
rotating, after the supplying of the processing liquid, the substrate held by the substrate holder at a higher speed than in the supplying of the processing liquid, without supplying the processing liquid, and
the suction opening is opened in the supplying of the processing liquid, and the suction opening is closed in the rotating of the substrate.

(10) A substrate processing method of processing a substrate by supplying a processing liquid to the substrate, performed in a substrate processing apparatus,
wherein the substrate processing apparatus includes:
a substrate holder configured to hold and rotate the substrate; and
a cup accommodating the substrate holder,
the cup includes:
an opening opened upwards to allow a transfer of the substrate;
a suction opening configured to suck in a gas flowing toward the cup from above the cup; and
an exhaust opening configured to exhaust the gas sucked in from the suction opening,
the suction opening is opened upwards at an outer side than the opening,
a flow path leading to the exhaust opening from the opening and a flow path leading to the exhaust opening from the suction opening are connected below the opening,
the substrate processing method includes:
supplying the processing liquid to the substrate held by the substrate holder; and
rotating, after the supplying of the processing liquid, the substrate held by the substrate holder at a higher speed than in the supplying of the processing liquid, without supplying the processing liquid, and
the suction opening is opened in the supplying of the processing liquid, and the suction
opening is closed in the rotating of the substrate.

According to the exemplary embodiment, by adjusting a gas flow for the substrate in the cup for use in the substrate processing apparatus, it is possible to realize a good processing.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A cup provided in a substrate processing apparatus configured to process a substrate by supplying a processing liquid to the substrate, the cup comprising:
an opening opened upwards to allow a transfer of the substrate;
a suction opening configured to suction in a gas flowing toward the cup from above the cup; and
an exhaust opening configured to exhaust the gas sucked in from the suction opening,
wherein the suction opening is opened upwards at an outer side and spaced from the opening, and
a first flow path leading to the exhaust opening from the opening and a second flow path leading to the exhaust opening from the suction opening are connected below the opening.

2. The cup of claim 1, further comprising:
an opening/closing device configured to open or close the suction opening.

3. The cup of claim 1, further comprising:
a suction path configured to guide a gas flow to the suction opening,
wherein an upper end of the suction path is opened upwards,
the suction path is divided into an inner portion and an outer portion, and
a pressure loss that occurs when a gas passes through the inner portion of the suction path is greater than a pressure loss that occurs when the gas passes through the outer portion of the suction path.

4. A substrate processing apparatus configured to process a substrate by supplying a processing liquid to the substrate, the substrate processing apparatus comprising:
a substrate holder configured to hold and rotate the substrate;
a processing liquid supply configured to supply the processing liquid to the substrate; and
a cup accommodating the substrate holder,
wherein the cup comprises:
an opening opened upwards to allow a transfer of the substrate;
a suction opening configured to suction in a gas flowing toward the cup from above the cup; and
an exhaust opening configured to exhaust the gas sucked in from the suction opening,
the suction opening is opened upwards at an outer side and spaced from the opening, and
a first flow path leading to the exhaust opening from the opening and a second flow path leading to the exhaust opening from the suction opening are connected below the opening.

5. The substrate processing apparatus of claim 4, further comprising:
a gas flow forming device configured to generate a downward gas flow from above the cup,
wherein the gas flow forming device comprises:
a blower provided above the cup, and configured to blow out a gas downwards; and
a gas flow forming member provided between the cup and the blower, and the gas flow forming member being configured to form the downward gas flow from the gas blown out from the blower, wherein
the gas flow forming member has, at a position facing the substrate holder, a device side opening through which a gas flow heading toward the substrate held by the substrate holder is formed, and
the gas flow forming member forms a stronger gas flow in a first region surrounding an outer periphery of the device side opening when viewed from a top, than in a second region outside the first region.

6. The substrate processing apparatus of claim 5, further comprising:
a suction path configured to guide the gas flow to the suction opening,
wherein an upper end of the suction path is opened upwards,
the suction path is divided into an inner portion and an outer portion,
a pressure loss that occurs when a gas passes through the inner portion of the suction path is greater than a pressure loss that occurs when the gas passes through the outer portion of the suction path, and
an inner peripheral edge of an upper end of the outer portion of the suction path is located at an outer side of the device side opening, when viewed from the top.

7. The substrate processing apparatus of claim 5,
wherein the gas flow forming member forms the stronger gas flow at an outer side than the opening of the cup when viewed from the top.

8. The substrate processing apparatus of claim 5,
wherein an entirety of the device side opening is located at an inner side than a circumferential edge of the substrate held by the substrate holder, when viewed from the top.

9. The substrate processing apparatus of claim 4,
wherein the cup further comprises an opening/closing device configured to open or close the suction opening,
the substrate processing apparatus further comprises a controller having a processor and a memory with a computer readable program stored therein that upon execution of the computer readable program by the processor configures the controller to,
supply the processing liquid to the substrate held by the substrate holder; and
rotate, after the supplying of the processing liquid, the substrate held by the substrate holder at a higher speed than in the supplying of the processing liquid, without supplying the processing liquid, and
the suction opening is opened in the supplying of the processing liquid, and the suction opening is closed in the rotating of the substrate.

10. A substrate processing method of processing a substrate by supplying a processing liquid to the substrate, performed in a substrate processing apparatus,
wherein the substrate processing apparatus comprises:
a substrate holder for holding and rotating the substrate; and
a cup accommodating the substrate holder,
the cup comprises:
an opening opened upwards to allow a transfer of the substrate;
a suction opening configured to suction in a gas flowing toward the cup from above the cup; and
an exhaust opening configured to exhaust the gas sucked in from the suction opening,
the suction opening is opened upwards at an outer side and spaced from the opening,
a first flow path leading to the exhaust opening from the opening and a second flow path leading to the exhaust opening from the suction opening are connected below the opening,
the substrate processing method comprises:
supplying the processing liquid to the substrate held by the substrate holder; and
rotating, after the supplying of the processing liquid, the substrate held by the substrate holder at a higher speed than in the supplying of the processing liquid, without supplying the processing liquid, and
the suction opening is opened in the supplying of the processing liquid, and the suction opening is closed in the rotating of the substrate.

11. The substrate processing method of claim 10, wherein the cup further includes:
an outer cup being an outer wall of the cup and having an outer peripheral wall and an inclined wall; and
an inner cup provided inside of the outer cup, and
the suction opening is provided in the inclined wall of the outer cup.

12. The substrate processing method of claim 11, wherein the outer peripheral wall has a cylindrical shape, and
the inclined wall forms a circular ring shape when viewed from a top of the cup.

13. The substrate processing method of claim 12, wherein the cup further includes:
a circular ring-shaped horizontal member;
a cylindrical outer peripheral vertical member; and
a cylindrical inner peripheral vertical member, wherein
a curved path is formed under the inner cup by the circular ring-shaped horizontal member, the cylindrical outer peripheral vertical member and the cylindrical inner peripheral vertical member.

14. The cup of claim 1, further comprising:
an outer cup being an outer wall of the cup and having an outer peripheral wall and an inclined wall; and
an inner cup provided inside of the outer cup,
wherein the suction opening is provided in the inclined wall of the outer cup.

15. The cup of claim 14, wherein the outer peripheral wall has a cylindrical shape, and
the inclined wall forms a circular ring shape when viewed from a top of the cup.

16. The cup of claim 15, further comprising
a circular ring-shaped horizontal member;
a cylindrical outer peripheral vertical member; and
a cylindrical inner peripheral vertical member, wherein
a curved path is formed under the inner cup by the circular ring-shaped horizontal member, the cylindrical outer peripheral vertical member and the cylindrical inner peripheral vertical member.

17. The substrate processing apparatus of claim 4, wherein the cup further includes:
an outer cup being an outer wall of the cup and having an outer peripheral wall and an inclined wall; and
an inner cup provided inside of the outer cup, and
the suction opening is provided in the inclined wall of the outer cup.

18. The substrate processing apparatus of claim 17, wherein the outer peripheral wall has a cylindrical shape, and
the inclined wall forms a circular ring shape when viewed from a top of the cup.

19. The substrate processing apparatus of claim 18, wherein the cup further includes:
a circular ring-shaped horizontal member;
a cylindrical outer peripheral vertical member; and
a cylindrical inner peripheral vertical member, and
a curved path is formed under the inner cup by the circular ring-shaped horizontal member, the cylindrical outer peripheral vertical member and the cylindrical inner peripheral vertical member.

20. The substrate processing apparatus of claim 4, further comprising:
an opening/closing device configured to open or close the suction opening.
